(19) United States
(12) Patent Application Publication
(10) Pub. No.: US 2022/0336398 A1
(43) Pub. Date: Oct. 20, 2022

(54) BUMP STRUCTURE OF CHIP

(71) Applicant: SITRONIX TECHNOLOGY CORP., Jhubei City (TW)

(72) Inventors: Kuo-Wei TSENG, Jhubei City (TW); Po-Chi CHEN, Jhubei City (TW)

(21) Appl. No.: 17/714,445

(22) Filed: Apr. 6, 2022

Related U.S. Application Data
(60) Provisional application No. 63/171,161, filed on Apr. 6, 2021.

(51) Int. Cl. H01L 23/00

(52) U.S. Cl. CPC H01L 24/14; H01L 24/13; H01L 24/73; H01L 24/32; H01L 24/16; H01L 2224/13013; H01L 2224/13015; H01L 2224/1403; H01L 2224/14051; H01L 2224/14177; H01L 2224/14155; H01L 2224/14151; H01L 2224/14131; H01L 2224/14133; H01L 2224/14134; H01L 2224/73204; H01L 2224/32227; H01L 2224/16227

(57) ABSTRACT

The present invention provides a bump structure of chip disposed on a surface of a chip and comprises a plurality of connecting-bump sets. Each connecting-bump set includes a first connecting hum and a second connecting hump. The first connecting bump and the second connecting bump include corresponding blocking structures. While disposing the chip on a board member, the blocking structure of the first connecting bump and the blocking structure of the second connecting bump block the conductive medium and retard the flow of the conductive medium. The conductive medium is forced to flow between the first connecting bump and the second connecting bump and thus preventing the conductive particles in the conductive medium from leaving the surfaces of the connecting bumps. In addition, there is a flow channel between the first and second connecting bumps. One or more width of the flow channel is between 0.1 μm and 8 μm.

### FIELD OF THE INVENTION

The present invention relates generally to a bump structure, and particularly to a bump structure disposed on the surface of chip for preventing the conductive particles of the conductive medium from leaving the surfaces of the bumps when the chip is disposed on a board member.

### BACKGROUND OF THE INVENTION

As time advances, electronic products are developed to be become light, thin, and miniature. Almost all various electronic products, for example, camcorders, notebook computers, smartphones, or other mobile devices, include a display for displaying information. Thereby, displays have become a key component in the electronic products.

To display images, driving chips should be included in a display. Driving chips are used for driving the panel for displaying images. In general, there are multiple technologies for disposing the driving chips on a panel. To adopt these technologies, the conductive medium, for example, an anisotropic conductive film (ACF), should be used. The conductive medium includes the conductive particles, which may contact the connecting bumps of driving chips and the electrical connecting members of the panel. Thereby, the driving chips may be connected electrically to the panel and then transmit the driving signals to the panel for driving the panel to display images.

According to the prior art, while disposing the driving chips on the panel, the conductive medium will flow arbitrarily on the surface of the driving chips and hence disallowing the conductive particles in the conductive medium to be distributed effective on the surfaces of the connecting humps of the driving chips. Thereby, the performance of the driving chips transmitting signals to the panel is affected, the panel might not function normally. In addition, this problem does not only exist in the driving chips of the panel, but it also appears in other chip types such as disposing the micro-controller chips on a circuit board. Thereby, it is urged to provide a bump structure that may prevent the conductive particles from leaving the surfaces of the connecting bumps.

### SUMMARY

An objective of the present invention is to provide a bump structure of chip, which comprises a plurality of connecting bumps disposed on the surface of a chip. Between the connecting bumps, there are flow channels. One or more width of the flow channels is between 0.1 μm and 8 μm. When the chip is disposed on a board member, since the space of the flow channels is limited, excess conductive particles leaving the surfaces of the connecting bumps to the flow channels may be prevented. Then a certain number of the conductive particles will be maintained on the surfaces of the connecting bumps.

Another objective of the present invention is to provide a bump structure of chip, which comprises a plurality of connecting-bump sets disposed on the surface of a chip. Each connecting-bump set includes two connecting bumps. Each of the two connecting bumps includes a blocking structure for blocking the conductive medium when the chip is disposed on the board member and reducing the flowing of the conductive medium. Thereby, the conductive particles leaving the surfaces of the connecting bumps are prevented, and a certain number of the conductive particles may be maintained on the surfaces of the connecting bumps.

The present invention provides a bump structure of chip disposed on the surface of a chip and comprising a plurality of connecting bumps. The connecting bumps are spaced with a flow channel therebetween. One or more width of the flow channel is between 0.1 μm and 8 μm.

The present invention further provides a bump structure of chip comprising a plurality of connecting-bump sets. Each connecting-bump set includes a first connecting bump and a second connecting bump. The first connecting bump and the second connecting bump are spaced. The first connecting bump includes a first protruding part located on a side surface of the first connecting bump. The second connecting bump includes a second recess part located on a side surface of the second connecting bump. The first protruding part of the first connecting bump corresponds to the second recess part of the second connecting bump. The first protruding part of the first connecting bump and the second recess part of the second connecting bump act as the blocking structures for retarding the flow of the conductive medium.

The present invention further provides a bump structure of chip comprising a plurality of connecting-hump sets. Each connecting-bump set includes a first connecting bump and a second connecting bump. The first connecting bump and the second connecting bump are spaced. The first connecting bump includes a first protruding part located on a side surface of the first connecting bump. The second connecting bump includes a second protruding part located on a side surface of the second connecting bump. The first protruding part of the first connecting bump corresponds to the second protruding part of the second connecting bump. The first protruding part of the first connecting bump and the second protruding part of the second connecting bump act as the blocking structures for retarding the flow of the conductive medium.

### BRIEF DESCRIPTION OF THE DRAWINGS

FIG. 1 shows a stereoscopic diagram according to the first embodiment of the present invention;

FIG. 2 shows a top view according to the first embodiment of the present invention;

FIG. 3 shows a cross-sectional view according to the first embodiment of the present invention;

FIG. 4 shows a stereoscopic diagram according to the second embodiment of the present invention;

FIG. 5 shows a top view according to the second embodiment of the present invention;

FIG. 6 shows a cross-sectional view according to the second embodiment of the present invention;

FIG. 7 shows a stereoscopic diagram according to the third embodiment of the present invention;

FIG. 8 shows a top view according to the third embodiment of the present invention;

FIG. 9 shows a cross-sectional view according to the third embodiment of the present invention;

FIG. 10 shows a stereoscopic diagram according to the fourth embodiment of the present invention; and

FIG. 11 shows a top view according to the fourth embodiment of the present invention.

### DETAILED DESCRIPTION

To make the structure and characteristics as well as the effectiveness of the present invention to be further understood and recognized, the detailed description of the present invention is provided as follows along with embodiments and accompanying figures.

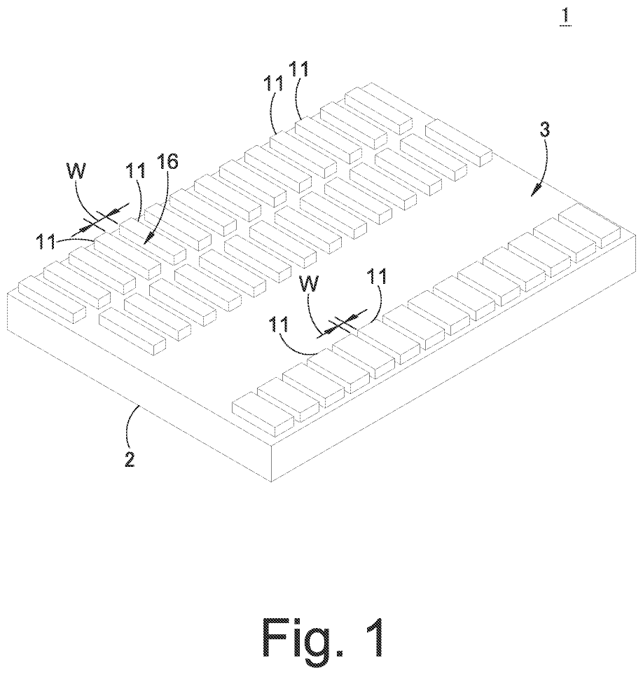

Please refer to FIG. 1, which shows a stereoscopic diagram according to the first embodiment of the present invention. As shown in the figure, a bump structure 1 according to the present invention is disposed on a surface 3 of a chip 2. The bump structure 1 comprises a plurality of connecting bumps 11 made of metal.

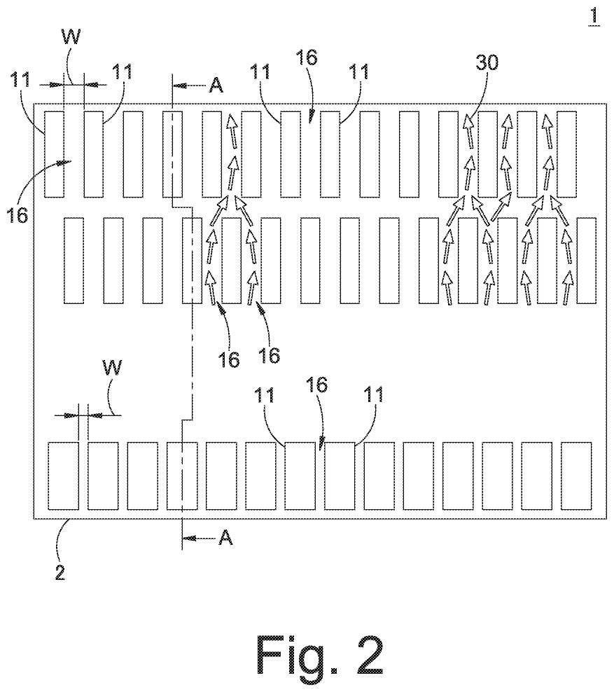

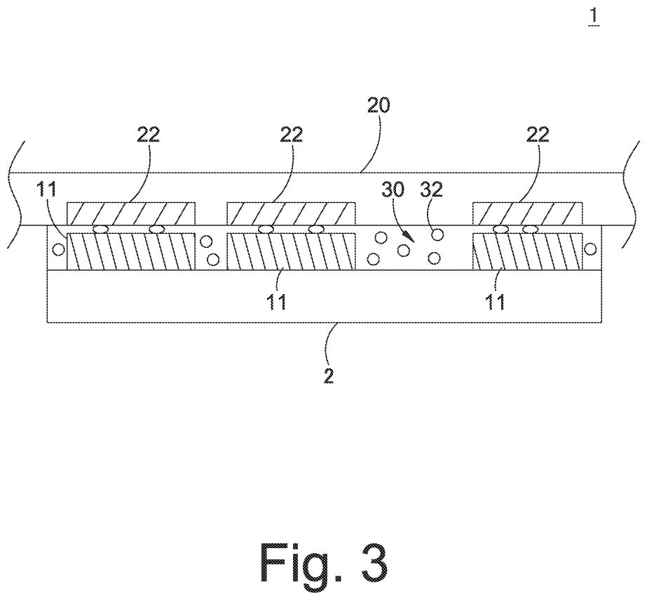

Please refer to FIG. 1 again and to FIGS. 2 and 3. FIG. 2 shows a top view according to the first embodiment of the present invention; FIG. 3 shows a cross-sectional view of FIG. 2 along the direction AA. As shown in the figure, the connecting bumps 11 are spaced with a flow channel 16 therebetween, respectively. One or more width W of the flow channel 16 is between 0.1 μm (micrometer) and 8 μm (micrometer) and preferably between 0.1 μm and 6 μm. A conductive medium 30 may flowing in the flow channel 16 and includes a plurality of conductive particles 32.

According to the present embodiment, the width W is the width of an inlet or/and an outlet of the flow channel 16. The width W is also the spacing between the connecting bumps 11. Limiting the width W of the flow channels 16 between the connecting bumps 11 means limiting the space of the flow channels 16, which is equivalent to limit the amount of the conductive particles 30 accommodated in the flow channels 16. While adding the conductive medium 30 on the surface 3 of the chip 2 and mounting the chip 2 on the board member 20, the chip 2 is stressed and thus enabling the conductive medium 30 to flow on the surface 3 of the chip 2. Since the space of the flow channels 16 is limited, excess conductive particles 32 leaving the surfaces of the connecting bumps 11 to the flow channels 16 may be prevented. In other word, a certain number of the conductive particles 32 may be maintained on the surfaces of the connecting bumps 11. The board member 30 may be a display panel or a circuit board.

According to the present embodiment, in addition to being linear, the flow channels 16 may be nonlinear as well. For example, they may be oblique or curved lines. The present embodiment is not limited to the examples.

Please refer again to FIGS. 1, 2, and 3. According to the present embodiment, the connecting bumps 11 correspond to one of a plurality of conductive members 22, respectively. The conductive members 22 are disposed on the board member 20. While adding the conductive medium 30 between the chip 2 and the board member 20 and mounting the chip 2 on the board member 20, the chip 2 is stressed and thus enabling the conductive medium 30 to flow on the surface 3 of the chip 2. Because the space of the flow channel 16 is limited, the flow channel 16 may accommodate only a small amount of the conductive medium 30 and the conductive particles 32. Thereby, the number of the conductive particles 32 leaving the surfaces of the connecting bumps 11 to the flow channel 16 may be reduced. That is to say, a certain number of the conductive particles 32 may be maintained on the surfaces of the connecting bumps 11. Hence, the connecting bumps 11 may be connected electrically with the conductive members 22 of the board member 20 firmly by means of the conductive particles 32 and thus ensuring the transmission between the chip 2 and the board member 20. According to the present embodiment, the conductive medium 30 may be, but not limited to, an anisotropic conductive film (ACF).

Please refer again to FIG. 1 and FIG. 2. The connecting bumps 11 mays be arranged in multiple rows. The connecting bumps 11 located at the rear row stagger the connecting bumps 11 located at the front row. In other words, the flow channels 16 between the connecting bumps 11 at the rear row will be directed to the bottom of the connecting bumps 11 at the front row. The arrows shown in FIG. 2 illustrate the flowing direction of the conductive medium 30. When the conductive medium 30 flows away from the flow channels 16 at the rear row, the conductive medium 30 will be blocked by the connecting bumps 11 at the front row and diverted, which will retard the flow of the conductive medium 30. Thereby, the amount of the conductive particles 32 leaving the surfaces of the connecting bumps 11 will reduced.

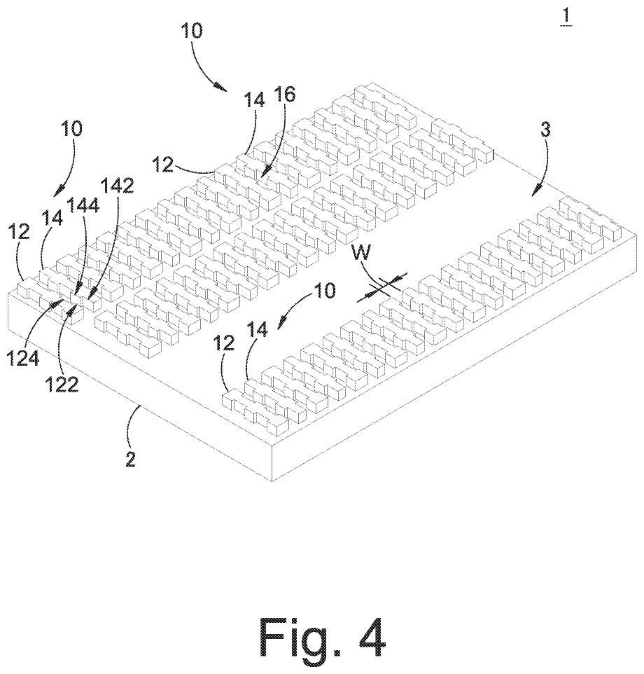

Please refer to FIG. 4, which shows a stereoscopic diagram according to the second embodiment of the present invention. As shown in the figure, the bump structure 1 according to the present invention comprises a plurality of connecting-bump sets 10. The connecting-bump sets are spaced and disposed on the surface 3 of the chip 2.

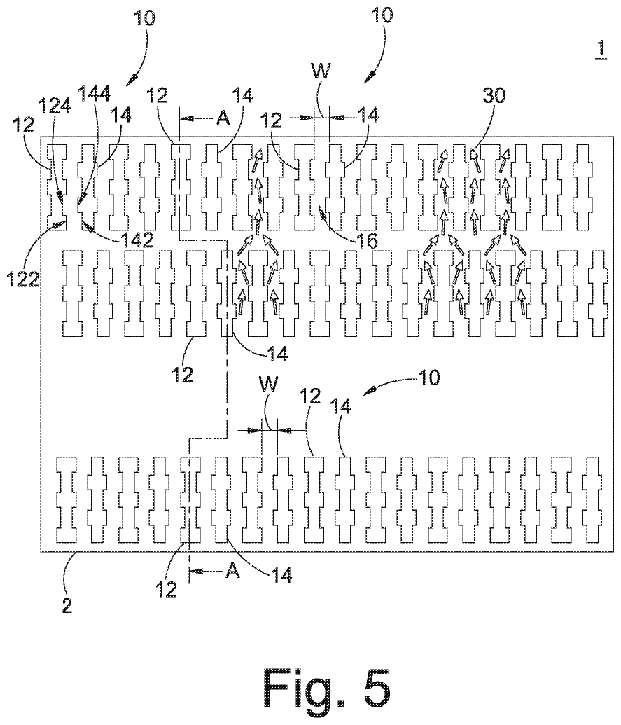

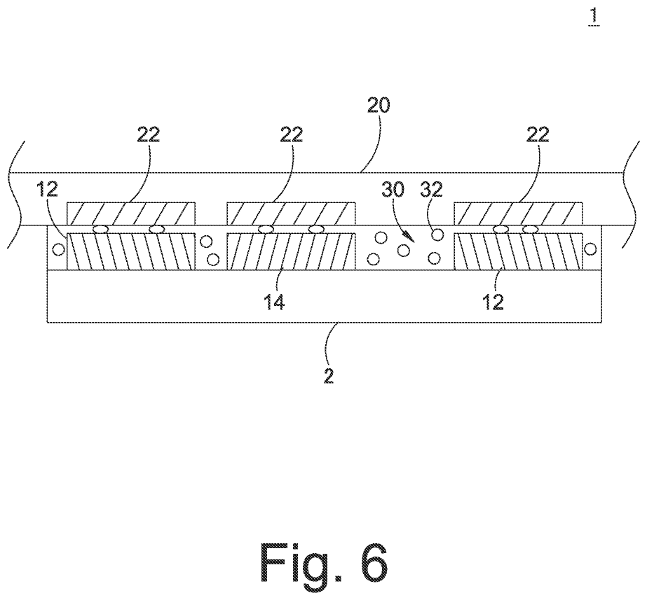

Please refer to FIG. 4 again and to FIGS. 5 and 6. FIG. 5 shows a top view according to the second embodiment of the present invention; FIG. 6 shows a cross-sectional view of FIG. 5 along the direction AA. According to the present embodiment, each connecting-bump set 10 includes a first connecting bump 12 and a second connecting bump 14. The first connecting bump 12 and the second connecting bump 14 are spaced to form a flow channel 16, The first connecting bump 12 includes a first protruding part 122 located on a side surface of the first connecting bump 12. The second connecting bump 14 includes a second recess part 142 located on a side surface of the second connecting bump 14. The first protruding part 122 corresponds to the second recess part 142. Namely, the first protruding part 122 faces the second recess part 142. Since their shapes are complementary, a nonlinear flow channel 16 is formed between the first connecting bump 12 and the second connecting bump 14.

According to the present embodiment, the first connecting bumps 12 and the second connecting bumps 14 correspond to the conductive members 22 disposed on the board member 20, respectively. The flow channel 16 is located between the first connecting bump 12 and the second connecting bump 14. The flow channel 16 passes by the first protruding part 122 of the first connecting bump 12 and the second recess part 144 of the second connecting bump 14. The first protruding part 122 and the second recess part 144 are blocking structures used for blocking the conductive medium 30, and therefore retarding the flow of the conductive medium 30. Thereby, the conductive particles 32 leaving the surfaces of the connecting bumps 12, 14 may be prevented. Then a certain number of the conductive particles 32 may be maintained on the surfaces of the connecting bumps 12, 14.

While adding the conductive medium 30 between the chip 2 and the board member 20 and mounting the chip 2 on the board member 20, the chip 2 is stressed and thus enabling the conductive medium 30 to flow on the surface 3 of the chip 2. The conductive medium 30 is blocked by the first protruding part 122 of the first connecting bump 12 and the second recess part 142 of the second connecting bump 14 and hence the flow is retarded. As shown in FIG. 5, the arrows indicate the flowing direction of the conductive medium 30.

Like the previous embodiment, one or more width W of the flow channel 16 between the first connecting bump 12 and the second connecting bump 14 as described above is between 0.1 μm and 8 μm, and preferably between 0.1 μm and 6 μm, for limiting the space of the flow channel 16. Thereby, the number of the conductive particles 32 leaving the surfaces of the connecting bumps 12, 14 may be reduced. In other words, a certain number of the conductive particles 32 may be maintained on the surfaces of the connecting bumps 12, 14. The width W is the width of the inlet or/and the outlet of the flow channel 16.

Please refer again to FIGS. 4, 5, and 6. The first connecting bump 12 further includes a first recess part 124 located on the side surface of the first connecting bump 12. The second connecting bump 14 further includes a second protruding part 144 located on the side surface of the second connecting bump 14. The first recess part 124 corresponds to the second protruding part 144. Namely, the first recess part 124 is opposing to the second protruding part 144 and they are complementary. The first recess part 124 and the second protruding part 144 are also blocking structures. The flow channel 16 further passes by the first recess part 124 and the second protruding part 144 and thus increasing zigzags of the flow channel 16 and further retarding the flow of the conductive medium 30. In addition, the connecting-bump sets 10 may be arranged in multiple rows. The connecting-bump sets 10 located at the rear row stagger the connecting-bump sets 10 located at the front row. In other words, the flow channels 16 between the connecting-bump sets 10 at the rear row will be directed to the bottom of the first connecting bump 12 or the second connecting bump 14 of the connecting-bump sets 10 at the front row. Thereby, the flow of the conductive medium 30 may be retarded.

According to the above embodiment, the first protruding part 122 and the first recess part 124 are the protruding portion and the recess portion of the first connecting hump 12, Thereby, the first connecting bump 12 may include a plurality of first protruding parts 122 and a plurality of first recess parts 124. Likewise, the second protruding part 144 and the second recess part 142 are the protruding portion and the recess portion of the second connecting bump 14. Thereby, the second connecting bump 14 may include a plurality of second protruding parts 144 and a plurality of second recess parts 142.

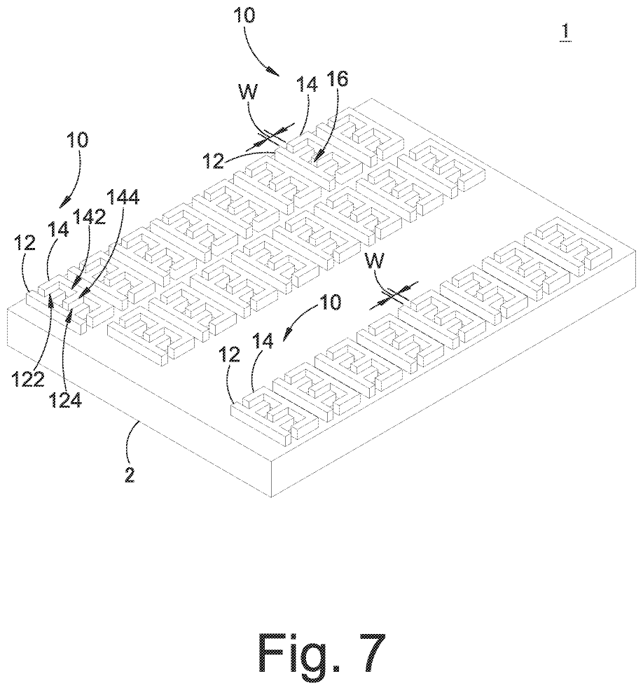

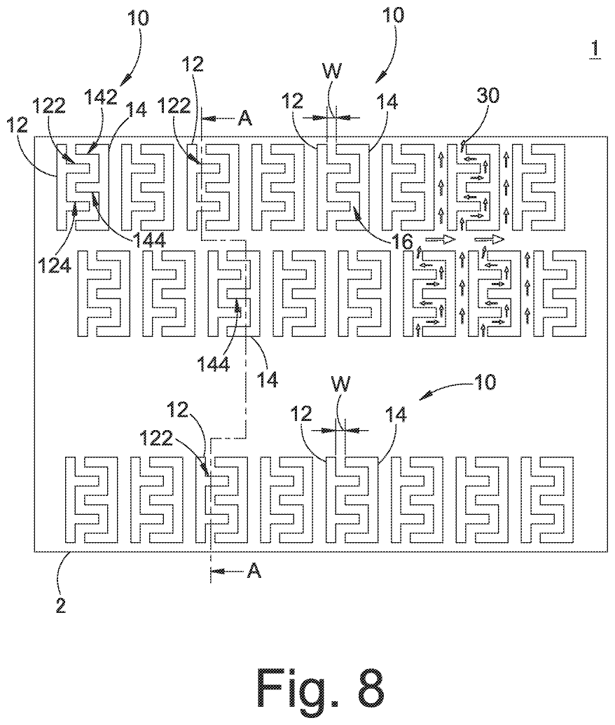

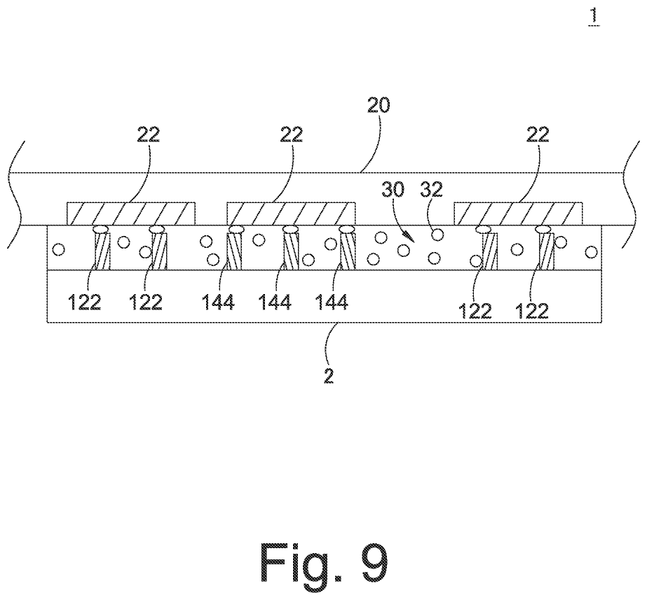

Please refer to FIGS. 7, 8, and 9. FIG. 7 shows a stereoscopic diagram according to the third embodiment of the present invention; FIG. 8 shows a top view according to the third embodiment of the present invention; and FIG. 9 shows a cross-sectional view of FIG. 8 along the direction AA. As shown in the figures, the difference between the present embodiment and the previous one is that, according to the present embodiment, the first protruding part 122 of the first connecting bump 12 extends into the second recess part 142 of the second connecting bump 14, Namely, the first protruding part 122 is located inside but not contacting the second recess part 142 and hence further detouring the flow channel 16 between the first connecting bump 12 and the second connecting bump 14 for blocking more the conductive medium 30. Thus, the conductive medium 30 is forced to be diverted. Consequently, the flow of the conductive medium 30 is further retarded.

According to the present embodiment, the second protruding part 144 of the second connecting bump 14 also extends to the first recess part 124 of the first connecting bump 12. In other words, the second protruding part 144 is located inside but not contacting the first recess art 124. According to the above description, the shape of the first connecting bump 12 and the shape of the second connecting bump 14 are complementary. As shown in FIG. 8, since the first protruding part 122 is located inside the second recess part 142 and the second protruding part 144 is located inside the first recess part 124, the flow channel 16 includes multiple corners, which force the conductive medium 30 in the flow channel 16 to be diverted repeatedly and hence retarding the flow of the conductive medium 30. As a result, it may be prevented that the conductive particles 32 leave the surfaces of the connecting bumps 12, 14. In addition, the conductive medium 30 may be guided to flow around the connecting bumps 12, 14 and the conductive particles 32 may be concentered on the surfaces of the connecting bumps 12, 14. The other structures and the operation principle according to the present embodiment are identical to those according to the second embodiment as described above. Hence, the details will not be described again.

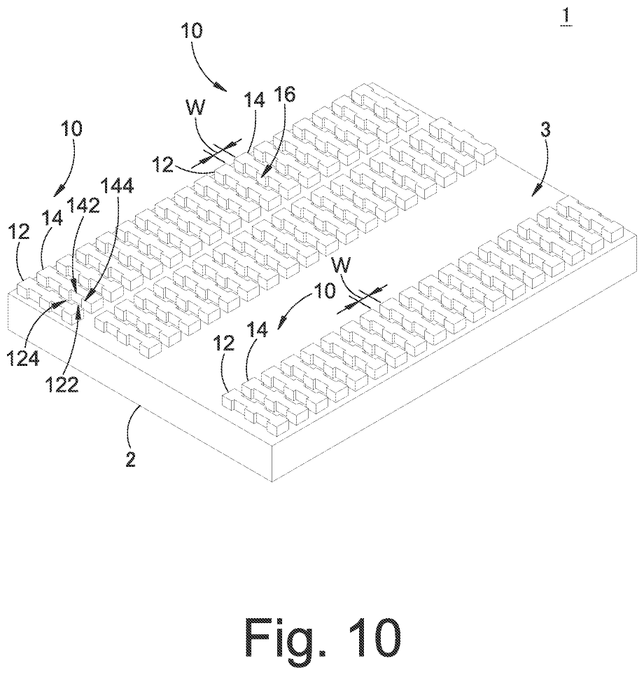

Please refer to FIG. 10, which shows a stereoscopic diagram according to the fourth embodiment of the present invention. As shown in the figure, the bump structure 1 comprises a plurality of connecting-bump sets 10. The connecting-bump sets 10 are spaced and disposed on the surface 3 of the chip 2.

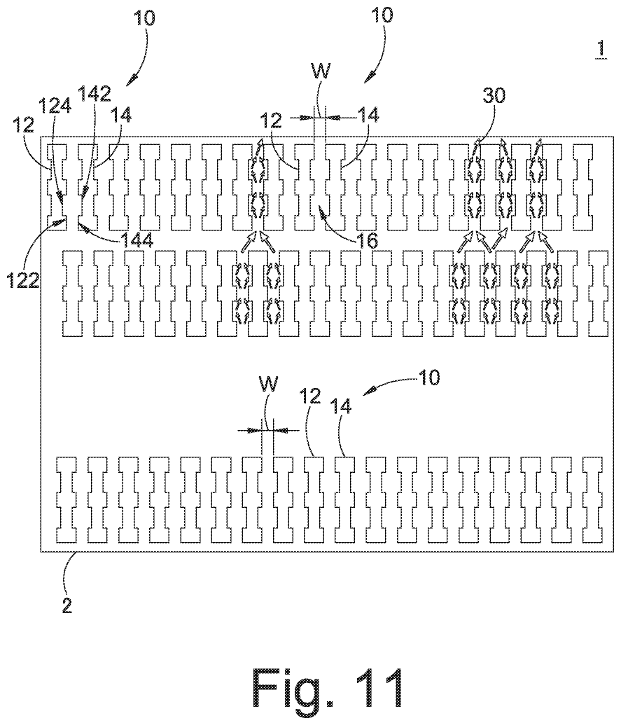

Please refer to FIG. 10 again and to FIG. 11, which shows a top view according to the fourth embodiment of the present invention. As shown in the figures, each connecting-bump set 10 includes a first connecting bump 12 and a second connecting bump 14. The first connecting bump 12 and the second connecting bump 14 are spaced. The first connecting bump 12 includes a first protruding part 122 located on a side surface of the first connecting bump 12. The second connecting bump 14 includes a second protruding part 144 located on a side surface of the second connecting bump 14. The first protruding part 122 corresponds to the second protruding part 144 and forming a nonlinear flow channel 16 between the first connecting bump 12 and the second connecting bump 14. The flow channel 16 passes by the first protruding part 122 of the first connecting hump 12 and the second protruding part 144 of the second connecting hump 14.

According to the present embodiment, the first connecting hump 12 further includes a first recess part 124 located on the side surface of the first connecting hump 12. The second connecting bump 14 further includes a second recess part 142 located on the side surface of the second connecting bump 14. The first recess part 124 corresponds to the second recess part 142. The flow channel 16 further passes by the first recess part 124 of the first connecting bump 12 and the second recess part 142 of the second connecting bump 14. The first protruding part 122, the first recess part 124, the second protruding part 144, and the second recess part 142 are used as blocking structures for blocking the conductive medium 30 and retarding the flow of the conductive medium 30. Since the first protruding part 122 is opposing to the second protruding part 144, the width of the flow channel 16 between the first protruding part 122 and the second protruding part 144 will be shrunk. Moreover, because the first recess part 124 is opposing to the second recess part 142, the width of the flow channel 16 between the first recess part 124 and the second recess part 142 will be increased. Since the width of the flow channel 16 according to the present embodiment varies, the flow rate of the conductive medium 30 varies accordingly. In addition, the first protruding part 122, the first recess part 124, the second protruding part 144, and the second recess part 142 block the conductive medium 30. Consequently, the flow of the conductive medium 30 will be slowed down.

According to the present embodiment, one or more width W of the flow channel 16 formed between the first connecting bump 12 and the second connecting hump 14 is between 0.1 μm and 8 μm and preferably between 0.1 μm and 6 μm. The width W is the width of the inlet or/and the outlet of the flow channel 16, The other structures and the operation principle according to the present embodiment are identical to those according to the second embodiment as described above. Hence, the details will not be described again.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

What is claimed is:

1. A bump structure of chip, disposed on a surface of a chip, and comprising a plurality of connecting-bump sets, each of said connecting-bump sets including a first connecting bump and a second connecting bump, said first connecting bump and said second connecting bump being spaced, said first connecting bump including a first protruding part located on a side surface of said first connecting bump, said second connecting bump including a second recess part located on a side surface of said second connecting bump, and said first protruding part of said first connecting bump corresponding to said second recess part of said second connecting bump.

2. The bump structure of chip of claim 1, wherein said first connecting bump includes a first recess part located on said side surface of said first connecting bump; said second connecting bump includes a second protruding part located on said side surface of said second connecting bump; and said first recess part corresponds to said second protruding part.

3. The bump structure of chip of claim 2, wherein a flow channel is formed between said first connecting hump and said second connecting bump; and said flow channel passes by said first protruding part of said first connecting hump, said second recess part of said second connecting bump, said first recess part of said first connecting bump, and said second protruding part of said second connecting bump.

4. The bump structure of chip of claim 1, wherein a flow channel is formed between said first connecting bump and said second connecting bump; and said flow channel passes by said first protruding part of said first connecting bump and said second recess part of said second connecting bump.

5. The bump structure of chip of claim 4, wherein one or more width of said flow channel is between 0.1 micrometer and 8 micrometers.

6. The bump structure of chip of claim 5, wherein said one or more width is a width of an inlet or/and an outlet of said flow channel.

7. The bump structure of chip of claim 4, wherein said flow channel is not linear.

8. A bump structure of chip, disposed on a surface of a chip, and comprising a plurality of connecting-bump sets, each of said connecting-bump sets including a first connecting bump and a second connecting bump, said first connecting bump and said second connecting bump being spaced, said first connecting bump including a first protruding part located on a side surface of said first connecting bump, said second connecting bump including a second protruding part located on a side surface of said second connecting bump, and said first protruding part of said first connecting bump corresponding to said second protruding part of said second connecting bump.

9. The bump structure of chip of claim 8, wherein said first connecting bump includes a first recess part located on said side surface of said first connecting bump; said second connecting bump includes a second recess part located on said side surface of said second connecting bump; and said first recess part corresponds to said second recess part.

10. The bump structure of chip of claim 9, wherein a flow channel is formed between said first connecting bump and said second connecting bump; and said flow channel passes by said first protruding part of said first connecting bump, said second protruding part of said second connecting bump, said first recess part of said first connecting bump, and said second recess part of said second connecting bump.

11. The bump structure of chip of claim 8, wherein a flow channel is formed between said first connecting bump and said second connecting bump; and said flow channel passes by said first protruding part of said first connecting hump and said second protruding part of said second connecting bump.

12. The bump structure of chip of claim 11, wherein one or more width of said flow channel is between 0.1 micrometer and 8 micrometers.

13. The bump structure of chip of claim 12, wherein said one or more width is a width of an inlet or/and an outlet of said flow channel.

14. The bump structure of chip of claim 11, wherein said flow channel is not linear.

15. A bump structure of chip, disposed on a surface of a chip, and comprising a plurality of connecting bumps, said connecting bumps being spaced, a flow channel formed between said connecting bumps, respectively, and one or more width of said flow channel being between 0.1 micrometer and 8 micrometers.

16. The hump structure of chip of claim 15, wherein said one or more wide is a width of an inlet or/and an outlet of said flow channel.

17. The bump structure of chip of claim 15, wherein said flow channel is not linear.

18. The bump structure of chip of claim 15, wherein said connecting bumps correspond to one of a plurality of conductive members, respectively and said conductive members are disposed on a board member.
